(19) United States
(12) Patent Application Publication
(10) Pub. No.: US 2024/0291449 A1
(43) Pub. Date: Aug. 29, 2024

(54) AMPLIFIER CIRCUIT, POWER AMPLIFIER CIRCUIT, AND COMMUNICATION DEVICE

(71) Applicant: Murata Manufacturing Co., Ltd., Kyoto (JP)

(72) Inventors: Makoto TABEI, Kyoto (JP); Kenji FURUSAWA, Kyoto (JP)

(21) Appl. No.: 18/584,365

(22) Filed: Feb. 22, 2024

(30) Foreign Application Priority Data
Feb. 27, 2023 (JP) 2023-028397

(51) Int. Cl. H03F 3/24; H03F 1/02

(52) U.S. Cl. CPC H03F 3/245; H03F 1/0205; H03F 2200/451

(57) ABSTRACT

An amplifier circuit includes: an input terminal; a first FET having a gate; a second FET connected, together with the first FET, between a power supply and a reference potential; an output terminal provided between the second FET and a load to output an amplified signal; a first voltage divider resistor circuit that divides a potential difference between the power supply and the reference potential, and generates a bias to be applied to a gate of the second FET; and a first switch element provided between the first voltage divider resistor circuit and the power supply and for turning on/off an electrical connection between the power supply and the first voltage divider resistor circuit. The first FET and the second FET have their adjacent drains and sources connected. The first switch element turns off when amplification operation by the first FET and the second FET is not performed.

### CROSS REFERENCE TO RELATED APPLICATION

This application claims priority from Japanese Patent Application No. 2023-028397 filed on Feb. 27, 2023. The content of this application is incorporated herein by reference in its entirety.

### BACKGROUND ART

The present disclosure relates to an amplifier circuit, a power amplifier circuit, and a communication device.

An amplifier circuit in which transistors, which are amplifier elements, are connected in a vertical stack, is known (for example, Japanese Patent No. 5420768). In the amplifier circuit of Japanese Patent No. 5420768, transistors at multiple stages are provided between a power supply and a reference potential. Moreover, among the transistors at multiple stages, a signal to be amplified is input to the base of the transistor closest to the ground potential. Then, among the transistors at multiple stages, a load is connected between the transistor closest to the power supply and the power supply.

### BRIEF SUMMARY

By the way, a communication device that utilizes multiple types of frequency bands may have an amplifier circuit corresponding to each frequency band. For example, an amplifier circuit corresponding to a high frequency band (high-band) and an amplifier circuit corresponding to a medium frequency band (mid-band) may be provided in or on a mobile communication device. The operating timings of those amplifier circuits are different from each other. If those amplifier circuits are connected to a common power supply line, the power supply voltage continues to be applied even when an amplifier circuit is not performing signal amplification (that is, when in a standby mode). Leakage current may be generated by the power supply voltage applied as above. There is an issue that this leakage current consumes power wastefully.

The present disclosure provides an amplifier circuit, a power amplifier circuit, and a communication device capable of suppressing power consumption due to leakage current.

An amplifier circuit according to an aspect of the present disclosure includes: an input terminal to which a signal to be amplified is input; a first FET having a gate to which the signal input to the input terminal is applied; a second FET connected, together with the first FET, between a power supply and a reference potential; an output terminal provided between the second FET and a load to output an amplified signal; a first voltage divider resistor circuit that divides a potential difference between the power supply and the reference potential, and generates a bias to be applied to a gate of the second FET; and a first switch element provided between the first voltage divider resistor circuit and the power supply and for turning on/off an electrical connection between the power supply and the first voltage divider resistor circuit. The first FET and the second FET have their adjacent drains and sources connected. The first switch element turns off when amplification operation by the first FET and the second FET is not performed.

A power amplifier circuit according to an aspect of the present disclosure in which the above-described amplifier circuit serves as a driver-stage amplifier circuit, further includes a power-stage amplifier circuit, with output of the driver-stage amplifier circuit serving as input.

A communication device according to an aspect of the present disclosure includes a plurality of the above-described power amplifier circuits, wherein the plurality of the power amplifier circuits selectively perform amplification operation based on a voltage supplied by a common power supply.

According to the present disclosure, power consumption due to leakage current can be suppressed.

### BRIEF DESCRIPTION OF THE DRAWINGS

FIG. 1 is a diagram illustrating a configuration example of a communication device including amplifier circuits;

FIG. 2 is a circuit diagram illustrating an amplifier circuit according to a comparative example;

FIG. 3 is a circuit diagram illustrating an amplifier circuit according to a first embodiment;

FIG. 4 is a diagram illustrating a configuration example of a switch in FIG. 3;

FIG. 5 is a diagram illustrating an operation example of the amplifier circuit illustrated in FIG. 3;

FIG. 6 is a diagram illustrating an operation example of the amplifier circuit illustrated in FIG. 3;

FIG. 7 is a diagram illustrating an operation example of the amplifier circuit illustrated in FIG. 3;

FIG. 8 is a circuit diagram illustrating an amplifier circuit according to a second embodiment;

FIG. 9 is a diagram illustrating simulation results for the case in which diodes in FIG. 8 are not connected;

FIG. 10 is a diagram illustrating the operation in the case where diodes are connected as in FIG. 8;

FIG. 11 is a circuit diagram illustrating an amplifier circuit according to a third embodiment; and

FIG. 12 is a diagram illustrating an amplifier circuit according to a modification.

### DETAILED DESCRIPTION

Hereinafter, embodiments of the present disclosure will be described in detail based on the drawings. In the description of each of the following embodiments, configuration portions identical or equivalent to other embodiments are given the same reference numerals, and descriptions thereof are abbreviated or omitted. The present disclosure is not limited by each embodiment. Moreover, the constituent elements of each embodiment may include those that are replaceable and easily substitutable by one skilled in the art, or those that are substantially identical. Note that the configurations described below can be combined as appropriate. In addition, the configurations can be omitted, replaced, or changed within the scope that does not deviate from the gist of the disclosure.

### Communication Device

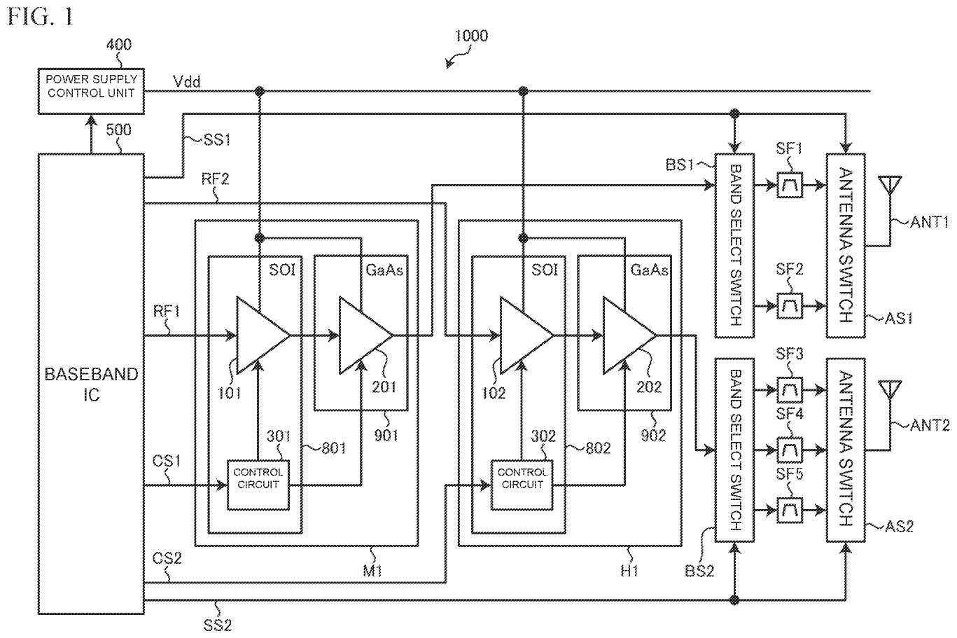

First, a communication device including amplifier circuits will be described. FIG. 1 is a diagram illustrating a configuration example of a communication device including amplifier circuits. In FIG. 1, a communication device 1000 includes a power amplifier circuit M1, a power amplifier circuit H1, band select switches BS1 and BS2, filters SF1 to SF5, antenna switches AS1 and AS2, antennas ANT1 and ANT2, a power supply control unit 400, and a baseband IC (Integrated Circuit) 500.

Each of the power amplifier circuit M1 and the power amplifier circuit H1 is a PA (Power Amplifier) module and has a function as a power amplifier circuit. When one of the power amplifier circuit M1 and the power amplifier circuit H1 is performing amplification operation, the other is in a standby mode in which amplification operation is not performed. That is, the power amplifier circuit M1 and the power amplifier circuit H1 selectively enter an operating state, and enter a standby mode when not in an operating state. Of the power amplifier circuit M1 and the power amplifier circuit H1, one that is in an amplification operating state operates in one of the following modes: High Power Mode (HPM), Middle Power Mode (MPM), and Low Power Mode (LPM).

The power amplifier circuit M1 includes amplifier circuits 101 and 201 and a control circuit 301. The amplifier circuit 101 is an amplifier circuit at a preceding stage, namely, a driver stage. The amplifier circuit 201 is an amplifier circuit at a subsequent stage, namely, a power stage. The amplifier circuit 201 at the power stage is configured by, for example, a bipolar transistor. The control circuit 301 is a circuit that outputs control signals for controlling the amplifier circuits 101 and 201. For example, the control circuit 301 inputs a gate bias control signal to the amplifier circuit 101. The control circuit 301 inputs a bias current to the amplifier circuit 201. The amplifier circuit 101 and the control circuit 301 are realized by, for example, an SOI (Silicon on Insulator) substrate 801. The amplifier circuit 201 is realized by, for example, a GaAs substrate 901.

The power amplifier circuit H1 includes amplifier circuits 102 and 202 and a control circuit 302. The amplifier circuit 102 is an amplifier circuit at a preceding stage, namely, a driver stage. The amplifier circuit 202 is an amplifier circuit at a subsequent stage, namely, a power stage. The amplifier circuit 202 at the power stage is configured by, for example, a bipolar transistor. The control circuit 302 is a circuit that outputs control signals for controlling the amplifier circuits 102 and 202. For example, the control circuit 302 inputs a gate bias control signal to the amplifier circuit 102. The control circuit 302 inputs a bias current to the amplifier circuit 202. In this example, the amplifier circuit 102 and the control circuit 302 are realized by, for example, an SOI substrate 802. The amplifier circuit 202 is realized by, for example, a GaAs substrate 902.

The band select switch BS1 is a switch that selects a frequency band based on a band select control signal SS1. The band select switch BS2 is a switch that selects a frequency band based on a band select control signal SS2.

The filters SF1 to SF5 are, for example, SAW (Surface Acoustic Wave) filters. Each of the filters SF1 and SF2 extracts signals in a required frequency band from the output of the band select switch BS1. Each of the filters SF3 to SF5 extracts signals in a required frequency band from the output of the band select switch BS2.

The antenna switch AS1 selects the output of the filter SF1 or the output of the SF2 based on the band select control signal SS1. The antenna switch AS2 selects the output of the filter SF3, the output of the filter SF4, or the output of the filter SF5 based on the band select control signal SS2. The antenna ANT1 emits a signal selected by the antenna switch AS1 as an electromagnetic wave. The antenna ANT2 emits a signal selected by the antenna switch AS2 as an electromagnetic wave.

The power supply control unit 400 is a power supply control module that outputs a power supply Vdd. The power supply Vdd is input to the power amplifier circuit M1 and the power amplifier circuit H1. The power supply control unit 400 includes, for example, a DC-DC (Direct Current-Direct Current) converter that converts a DC voltage level.

The baseband IC 500 transmits RF signals to the power amplifier circuit M1 and the power amplifier circuit H1. The baseband IC 500 also sends control signals CS1 and CS2 and the band select control signals SS1 and SS2 to the respective parts in the communication device 1000 in accordance with the to-be-output frequency band. The baseband IC 500 sends control signals to the band select switches BS1 and BS2 and the antenna switches AS1 and AS2.

### Operation

The baseband IC 500 controls each part of the communication device 1000 to ensure that the signal passes through a desired path, and transmits an RF signal. The RF signal is input to one of the power amplifier circuit M1 and the power amplifier circuit H1 that is in an amplification operating state. For example, when the power amplifier circuit H1 is in an amplification operating state, an RF signal RF2 is input to the power amplifier circuit H1. The power amplifier circuit H1 performs amplification operation on the RF signal RF2 using the amplifier circuits 102 and 202. The amplified signal is output from the antenna ANT2 by way of the band select switch BS2, the filter SF3, SR4, or SF5, and the antenna switch AS2.

Moreover, when the power amplifier circuit M1 is in an amplification operating state, an RF signal RF1 is input to the power amplifier circuit M1. The power amplifier circuit M1 performs amplification operation on the RF signal RF1 using the amplifier circuits 101 and 201. The amplified signal is output from the antenna ANT1 by way of the band select switch BS1, the filter SF1 or SF2, and the antenna switch AS1.

The voltage value of the power supply Vdd output by the power supply control unit 400 is controlled according to the output power of the power amplifier circuit M1 or the power amplifier circuit H1 that is in an operating state. Therefore, the voltage value of the power supply Vdd fluctuates. For example, the voltage value of the power supply Vdd fluctuates in the case of performing average power tracking (APT) or envelope tracking (ET).

The control circuit 301 is a circuit that outputs control signals for controlling the amplifier circuits 101 and 201. In this example, it is assumed that the power amplifier circuit M1 is in a standby mode and the power amplifier circuit H1 is in an operating state. The RF signal RF1 is not input to the power amplifier circuit M1, which is in a standby mode.

A comparative example will be described below to facilitate the understanding of the embodiments.

### Comparative Example

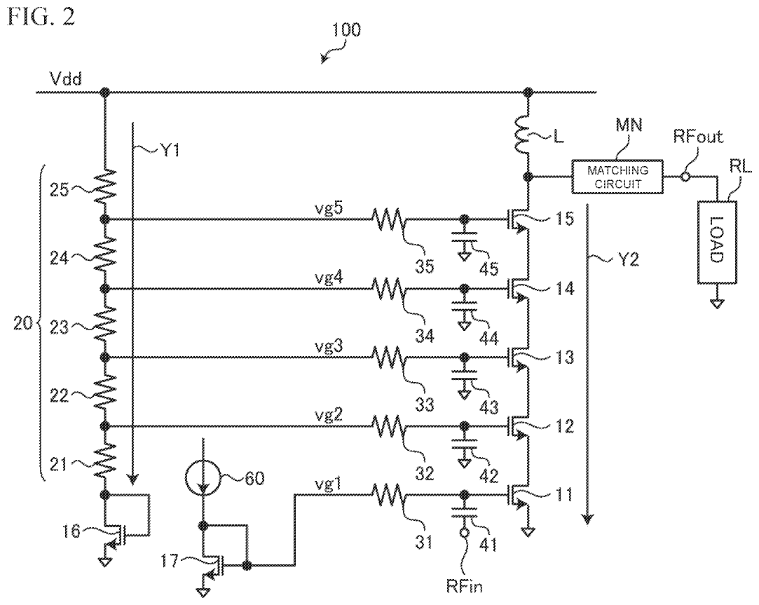

FIG. 2 is a circuit diagram illustrating an amplifier circuit 100 according to the comparative example. The amplifier circuit 100 corresponds to the amplifier circuit 101 or 102 at the driver stage in FIG. 1. In FIG. 2, the amplifier circuit 100 of this example includes a plurality of field effect transistors, namely, FETs (hereinafter referred to as FETs). The amplifier circuit 100 includes FETs 11, 12, 13, 14, and 15, resistors 21, 22, 23, 24, and 25, resistors 31, 32, 33, 34, and 35, capacitors 41, 42, 43, 44, and 45, and an FET 16.

The FETs 11, 12, 13, 14, and 15 are provided between a reference potential and the power supply Vdd. The FETs 11, 12, 13, 14, and 15 are connected in a vertical stack by having their adjacent drains and sources connected. That is, the drain of the FET 11 is connected to the reference potential, and the source of the FET 11 is connected to the drain of the FET 12. The source of the FET 12 is connected to the drain of the FET 13. The source of the FET 13 is connected to the drain of the FET 14. The source of the FET 14 is connected to the drain of the FET 15. The source of the FET 15 is connected to the power supply Vdd with a choke coil L interposed therebetween. In this paper, the FET 11 may be referred to as a first FET, the FET 12 as a second FET, the FET 13 as a third FET, the FET 14 as a fourth FET, and the FET 15 as a fifth FET, respectively. The reference potential is, for example, a ground potential. The same is true in the following description.

The power supply Vdd is a variable power supply, and its voltage value fluctuates, rather than being a fixed value. An output terminal RFout is connected between the choke coil L and the FET 15 with a matching circuit MN interposed therebetween. A load RL is connected to the output terminal RFout. Note that, when viewed from the drain of the FET 15, a portion including the choke coil L and the matching circuit MN, along with the load RL, appears as a load impedance. The output terminal RFout is connected to the power supply Vdd with the choke coil L interposed therebetween. The output terminal RFout is provided between the FET 12, which is the second FET, and the load RL.

The resistor 31 and the capacitor 41 are provided corresponding to the FET 11. A first end of the resistor 31 and a first end of the capacitor 41 are respectively connected to the gate of the FET 11. A second end of the capacitor 41 is connected to an input terminal RFin. A signal to be amplified is input to the input terminal RFin.

The resistor 32 and the capacitor 42 are provided corresponding to the FET 12. A first end of the resistor 32 and a first end of the capacitor 42 are respectively connected to the gate of the FET 12. A second end of the capacitor 42 is connected to the reference potential.

The resistor 33 and the capacitor 43 are provided corresponding to the FET 13. A first end of the resistor 33 and a first end of the capacitor 43 are respectively connected to the gate of the FET 13. A second end of the capacitor 43 is connected to the reference potential.

The resistor 34 and the capacitor 44 are provided corresponding to the FET 14. A first end of the resistor 34 and a first end of the capacitor 44 are respectively connected to the gate of the FET 14. A second end of the capacitor 44 is connected to the reference potential.

The resistor 35 and the capacitor 45 are provided corresponding to the FET 15. A first end of the resistor 35 and a first end of the capacitor 45 are respectively connected to the gate of the FET 15. A second end of the capacitor 45 is connected to the reference potential.

The FET 16 has its drain and gate connected, which is a so-called diode connection. The FET 16 is provided between the resistor 21 and the reference potential.

The resistance values of the resistors 31, 32, 33, 34, and 35 are, for example, several [kΩ]. Also, the capacitance values of the capacitors 41, 42, 43, 44, and 45 range from, for example, several tens of [pF] to several [pF].

The resistors 21, 22, 23, 24, and 25 are ladder resistors connected in series between the power supply Vdd and the reference potential. The resistors 21, 22, 23, 24, and 25 become a voltage divider resistor circuit 20. The voltage divider resistor circuit 20 divides the potential difference between the power supply Vdd and the reference potential, and generates a bias to be applied to each gate of the FET 12 to the FET 15. By realizing the resistors 21, 22, 23, 24, and 25 with identical ladder resistors, it is possible to prevent reversal of gate bias in each stage due to mismatches between resistors. Here, “identical ladder resistors” refer to ladder resistors that are identical in terms of manufacturing process and materials.

A first end of the resistor 21 is connected to the drain and gate of the FET 16. The first end of the resistor 21 is connected to the reference potential with a diode by the FET 16 interposed therebetween. The FET 16 is connected to the reference potential side of the voltage divider resistor circuit 20. Therefore, the FET 16 is provided between the voltage divider resistor circuit 20 and the reference potential.

In the voltage divider resistor circuit 20, the resistor 21 and the resistor 22 are connected in series. The connection point between the resistor 21 and the resistor 22 is connected to the second end of the resistor 32. The voltage at the connection point between the resistor 21 and the resistor 22 is applied as a bias vg2 to the gate of the FET 12. The resistor 22 and the resistor 23 are connected in series. The connection point between the resistor 22 and the resistor 23 is connected to the second end of the resistor 33. The voltage at the connection point between the resistor 22 and the resistor 23 is applied as a bias vg3 to the gate of the FET 13. The resistor 23 and the resistor 24 are connected in series. The connection point between the resistor 23 and the resistor 24 is connected to the second end of the resistor 34. The voltage at the connection point between the resistor 23 and the resistor 24 is applied as a bias vg4 to the gate of the FET 14. The resistor 24 and the resistor 25 are connected in series. The connection point between the resistor 24 and the resistor 25 is connected to the second end of the resistor 35. The voltage at the connection point between the resistor 24 and the resistor 25 is applied as a bias vg5 to the gate of the FET 15.

Also, in FIG. 2, the amplifier circuit 100 of this example includes an FET 17 and a constant current source 60. The constant current source 60 outputs a constant current. The FET 17 is connected to the output side of the constant current source 60. The FET 17 has its drain and gate connected, which is a so-called diode connection. A second end of the resistor 31 is connected to the FET 17. The FET 17 is a replica transistor that forms a current mirror circuit along with the first FET 11. The current mirror circuit formed of the FET 11 and the FET 17 causes a current proportional to the constant current output from the constant current source 60 to flow between the drain and the source of the FET 11.

### Operation of Comparative Example

In the amplifier circuit 100 illustrated in FIG. 2, each gate of the FET 12 to the FET 15 is applied with a bias (that is, a gate a bias) generated by the resistor voltage division of the voltage divider resistor circuit 20. The amplifier circuit 100 amplifies a radio frequency signal input to the input terminal RFin. The amplifier circuit 100 outputs the amplified signal from the output terminal RFout.

Here, there are cases in which one of the power amplifier circuit M1 and the power amplifier circuit H1 illustrated in FIG. 1 is performing amplification operation, while the other power amplifier circuit is not performing amplification operation. Since the power amplifier circuit M1 and the power amplifier circuit H1 share the power supply Vdd, the power supply Vdd is also supplied to the power amplifier circuit that is not performing power amplification.

In the case where the amplifier circuit 100 illustrated in FIG. 2 is not performing amplification operation, the amplifier circuit 100 is in a standby mode. Even in a standby mode, the amplifier circuit 100 is supplied with the power supply Vdd. Therefore, even in a standby mode, leakage current flows through the voltage divider resistor circuit 20, as indicated by arrow Y1. That is, leakage current flows from the power supply Vdd through the voltage divider resistor circuit 20 towards the FET 16. Also, as indicated by arrow Y2, leakage current flows from the power supply Vdd through the choke coil L, from the FET 15 towards the FET 11.

That is, when the amplifier circuit 100 is connected to a power supply line common to another amplifier circuit with a different operating timing, the voltage of the power supply Vdd will be applied to the amplifier circuit 100 even if the amplifier circuit 100 is not performing power amplification (that is, when in a standby mode). At this time, leakage current may be generated by the power supply Vdd. For an amplifier circuit in a standby mode, there is a challenge in reducing the leakage current due to the power supply Vdd.

### First Embodiment

The embodiments will now be described.

### Configuration

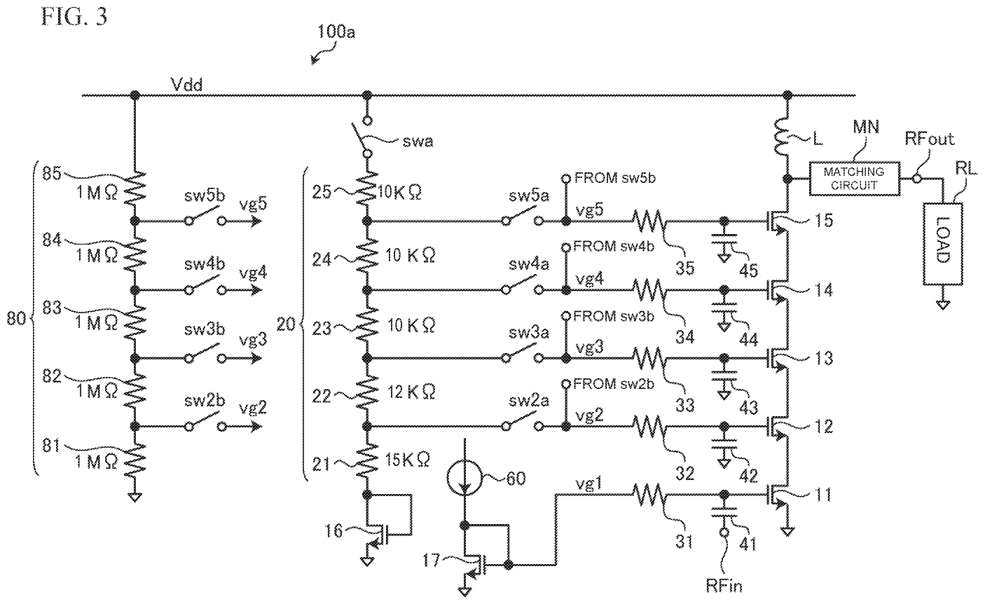

FIG. 3 is a circuit diagram illustrating an amplifier circuit 100a according to a first embodiment. The amplifier circuit 100a corresponds to the amplifier circuit 101 or 102 at the driver stage in FIG. 1. In FIG. 3, the amplifier circuit 100a is a configuration in which the amplifier circuit 100 described with reference to FIG. 2 is supplemented with a voltage divider resistor circuit 80, a switch swa, which is a first switch element, switches sw2a, sw3a, sw4a and sw5a, which are second switch elements, and switches sw2b, sw3b, sw4b and sw5b, which are third switch elements. In this paper, the voltage divider resistor circuit 20 may be referred to as a first voltage divider resistor circuit, and the voltage divider resistor circuit 80 as a second voltage divider resistor circuit.

The switches sw2a, sw3a, sw4a and sw5a, which are the second switch elements, are provided between the voltage divider resistor circuit 20 and the FET 12 to the FET 15. The voltage divider resistor circuit 20 supplies biases to the FET 12 to the FET 15 by way of the switches sw2a, sw3a, sw4a, and sw5a.

The switches sw2b, sw3b, sw4b, and sw5b, which are the third switch elements, are provided between the voltage divider resistor circuit 80 and the FET 12 to the FET 15. The voltage divider resistor circuit 80 supplies biases to the FET 12 to the FET 15 by way of the switches sw2b, sw3b, sw4b, and sw5b.

The voltage divider resistor circuit 80, which is the second voltage divider resistor circuit, is provided between the power supply Vdd and the reference potential. The voltage divider resistor circuit 80 includes resistors 81, 82, 83, 84 and 85. The voltage divider resistor circuit 80 divides the potential difference between the power supply Vdd and the reference potential, and generates biases to be applied to the gates of the FET 12 to the FET 15.

The resistance value of each of the resistors 81, 82, 83, 84, and 85 included in the voltage divider resistor circuit 80 is greater than the resistance value of each of the resistors 21, 22, 23, 24, and 25 included in the voltage divider resistor circuit 20. For example, in the voltage divider resistor circuit 20, the resistor 21 is 15 [kΩ], the resistor 22 is 12 [kΩ], and the resistor 23, the resistor 24, and the resistor 25 are 10 [kΩ]. Also, for example, in the voltage divider resistor circuit 80, the resistors 81 to 85 are all 1 [MΩ].

The switch swa is provided between the voltage divider resistor circuit 20 and the power supply Vdd. The switch swa is a switch element for turning on/off the electrical connection between the power supply Vdd and the voltage divider resistor circuit 20. The switch swa turns on when the amplification operation by the amplifier circuit 100a is performed. In addition, the switch swa turns off when the amplification operation by the amplifier circuit 100a is not performed. That is, the switch swa turns on when the amplification operation by the FET 11 to the FET 15 is performed. In addition, the switch swa turns off when the amplification operation by the FET 11 to the FET 15 is not performed (that is, when in a standby mode).

The switches sw2a, sw3a, sw4a and sw5a simultaneously turn on or off. The switches sw2b, sw3b, sw4b and sw5b simultaneously turn on or off.

The switches sw2a, sw3a, sw4a and sw5a and the switches sw2b, sw3b, sw4b and sw5b selectively turn on or off. That is, when the switches sw2a, sw3a, sw4a and sw5a are in the on state, the switches sw2b, sw3b, sw4b and sw5b are in the off state. When the switches sw2a, sw3a, sw4a and sw5a are in the off state, the switches sw2b, sw3b, sw4b and sw5b are in the on state. In this way, the switches sw2a, sw3a, sw4a and sw5a and the switches sw2b, sw3b, sw4b and sw5b turn on/off independently.

The switch swa and the switches sw2a, sw3a, sw4a and sw5a turn on/off in conjunction. That is, the switch swa and the switches sw2a, sw3a, sw4a and sw5a simultaneously turn on or off. That is, when the switch swa is in the on state, the switches sw2a, sw3a, sw4a, and sw5a are in the on state. When the switch swa is in the off state, the switches sw2a, sw3a, sw4a, and sw5a are in the off state. In short, the switch swa, which is the first switch element, turns on when the switches sw2a, sw3a, sw4a and sw5a, which are the second switch elements, turn on. In addition, the switch swa turns off when the switches sw2a, sw3a, sw4a and sw5a turn off. Furthermore, the switches sw2a, sw3a, sw4a and sw5a, which are the second switch elements, turn off when the switches sw2b, sw3b, sw4b and sw5b, which are the third switch elements, turn on. Also, the switches sw2a, sw3a, sw4a and sw5a turn on when the switches sw2b, sw3b, sw4b and sw5b turn off.

### Configuration Example of Switches

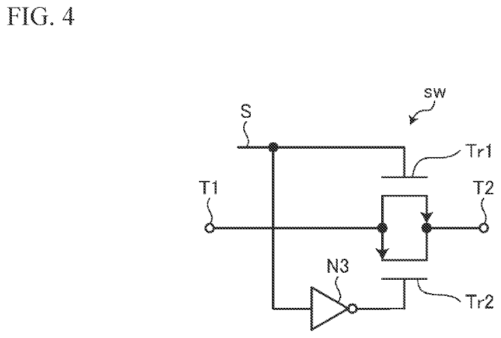

FIG. 4 is a diagram illustrating a configuration example of a switch in FIG. 3. A switch sw illustrated in FIG. 4 indicates a configuration example of each switch in FIG. 3. In FIG. 4, the switch sw includes an N-type MOS transistor Tr1, a P-type MOS transistor Tr2, an inverter (NOT circuit) N3, and terminals T1 and T2. The inverter N3 inverts a control signal S.

The N-type MOS transistor Tr1 and the P-type MOS transistor Tr2 have their sources connected together, and their drains connected together. Signals inverted from each other by the inverter N3 are applied to the gate of the N-type MOS transistor Tr1 and the gate of the P-type MOS transistor Tr2. Therefore, the N-type MOS transistor Tr1 and the P-type MOS transistor Tr2 simultaneously turn on and simultaneously turn off. Thus, based on the control signal S, the switch sw turns on, allowing a signal to pass between the terminal T1 and the terminal T2, or turns off, not allowing the signal to pass between the terminal T1 and the terminal T2. Therefore, the switch sw can turn on/off the electrical connection between the terminal T1 and the terminal T2. In each subsequent embodiment, the configuration of each switch used is the same as or similar to that illustrated in FIG. 4.

### Operation

Referring back to FIG. 3, in the case of performing amplification operation using the amplifier circuit 100a, the switch swa is turned on. Accordingly, each gate of the FET 12 to the FET 15 is applied with a bias (i.e., a gate bias) generated by the resistor voltage division of the voltage divider resistor circuit 20. The amplifier circuit 100a amplifies a radio frequency signal input to the input terminal RFin. The amplifier circuit 100a outputs the amplified signal from the output terminal RFout.

When in a standby mode in which amplification operation is not performed by the amplifier circuit 100a illustrated in FIG. 3, the switch swa is turned off. Accordingly, the voltage due to the power supply Vdd is not applied to the voltage divider resistor circuit 20. However, it is suitable to apply biases in the amplifier circuit 100a for countermeasures against breakdown voltage. Therefore, to achieve a minimum leakage current, biases are generated by the voltage divider resistor circuit 80 with resistors having large resistance values.

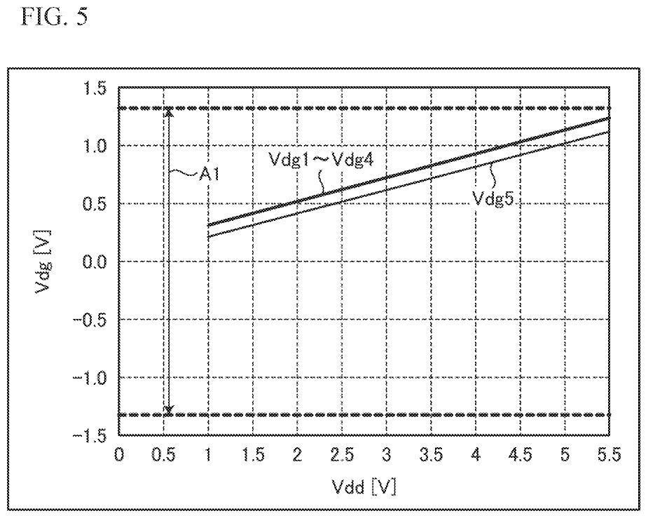

FIGS. 5, 6, and 7 are diagrams illustrating operation examples of the amplifier circuit 100a illustrated in FIG. 3. FIG. 5 is a diagram illustrating the simulation results of the potential difference between the drain and the gate. FIG. 5 is a diagram illustrating the simulation results in a standby mode where the amplifier circuit 100a is not performing amplification operation.

In FIG. 5, the horizontal axis is the voltage value [V] of the power supply Vdd, and the vertical axis is the value [V] of the drain-gate voltage Vdg. As illustrated in FIG. 5, as the voltage value of the power supply Vdd rises from 1 [V], the values of the voltages Vdg1 to Vdg4 corresponding to the biases vg1 to vg5 change according to that change. With regard to the voltages Vdg1 to Vdg4, none exceeds the unbroken area A1. Note that the unbroken area A1 is an area where the FET does not reach breakdown as long as it operates within that area.

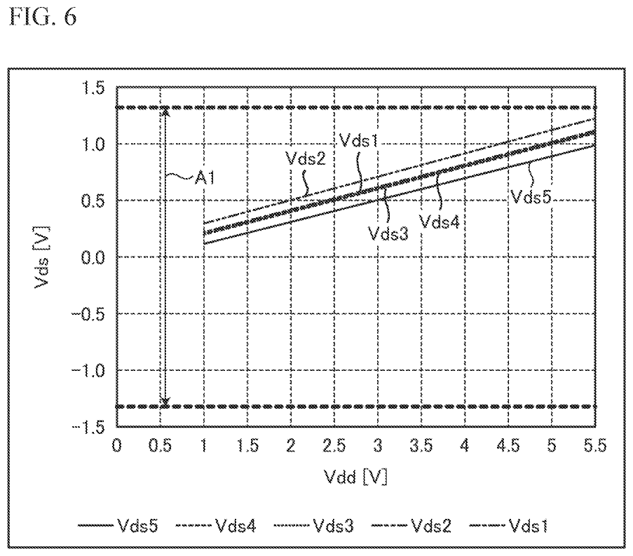

FIG. 6 is a diagram illustrating the simulation results of the drain-source potential difference. FIG. 6 illustrates the simulation results in a standby mode where the amplifier circuit 100a is not performing amplification operation.

In FIG. 6, the horizontal axis is the voltage value [V] of the power supply Vdd, and the vertical axis is the value [V] of the drain-source voltage Vds. As illustrated in FIG. 6, as the voltage value of the power supply Vdd rises from 1 [V], the values of the voltages Vds1 to Vds5 corresponding to the biases vg1 to vg5 change according to that change. With regard to the voltages Vds1 to Vds5, none exceeds the unbroken area A1.

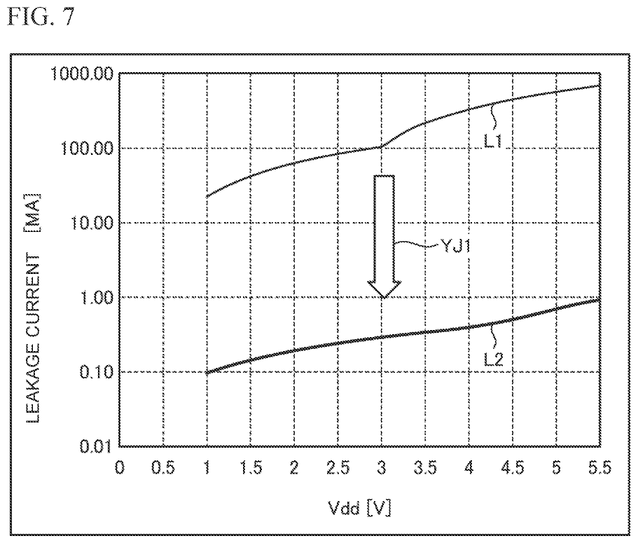

FIG. 7 is a diagram illustrating the simulation results of leakage current. In FIG. 7, the horizontal axis is the voltage value [V] of the power supply Vdd, and the vertical axis is the value [A] of leakage current. In FIG. 7, a current L1 is a leakage current during the amplification operation of the amplifier circuit 100a. In addition, a leakage current L2 is a leakage current when in a standby mode in which the first voltage divider resistor circuit 20 is disconnected and the second voltage divider resistor circuit 80 is connected. That is, the switch swa turns off, and, in conjunction with this, the switches sw2a, sw3a, sw4a and sw5a turn off, while the switches sw2b, sw3b, sw4b and sw5b turn on. This connects the second voltage divider resistor circuit 80, which includes resistors with resistance values greater than the resistors of the first voltage divider resistor circuit 20. By connecting the second voltage divider resistor circuit 80 with large resistance values, the current value of the leakage current L2 can be reduced, as indicated by arrow YJ1.

### Effects

As described above, according to the amplifier circuit 100a according to the first embodiment, by switching to the voltage divider resistor circuit 80 with high resistance values when in a standby mode, the biases can be controlled so as not to exceed the breakdown voltage in terms of DC, while suppressing the leakage current as well. When the voltage value of the power supply Vdd fluctuates, the biases are controlled so as not to exceed the breakdown voltage in terms of DC, while suppressing the leakage current as well. By suppressing the leakage current, optional power consumption can be prevented. Especially in a communication device powered by a battery, reducing power consumption can extend the battery life.

### Second Embodiment

A second embodiment will now be described. As described above, according to the amplifier circuit 100a, by switching to the voltage divider resistor circuit 80 with high resistance values when in a standby mode, leakage current can be suppressed while controlling the biases so as not to exceed the breakdown voltage in terms of DC.

However, if the voltage divider resistor circuit 80 with high resistance values is used, the resistors 82 to 85 with high resistance values in the voltage divider resistor circuit 80 and the capacitors 42 to 45 will form a low-pass filter (so-called RC circuit). Because the resistors 82 to 85 in the voltage divider resistor circuit 80 are large, the RC time constant becomes large. Due to the RC time constant of this low-pass filter, when the voltage of the power supply Vdd fluctuates, the biases applied to the gates of the FETs 12 to 15 fail to follow the changes, resulting in a delay. This delay may potentially lead to a temporary exceeding of the breakdown voltage. In addition, when transitioning from a standby mode to an operating state, there is a possibility that the biases applied to the gates of some FETs are not rapidly switched due to the influence of the low-pass filters described above. Accordingly, in the second embodiment, diodes are added.

### Configuration

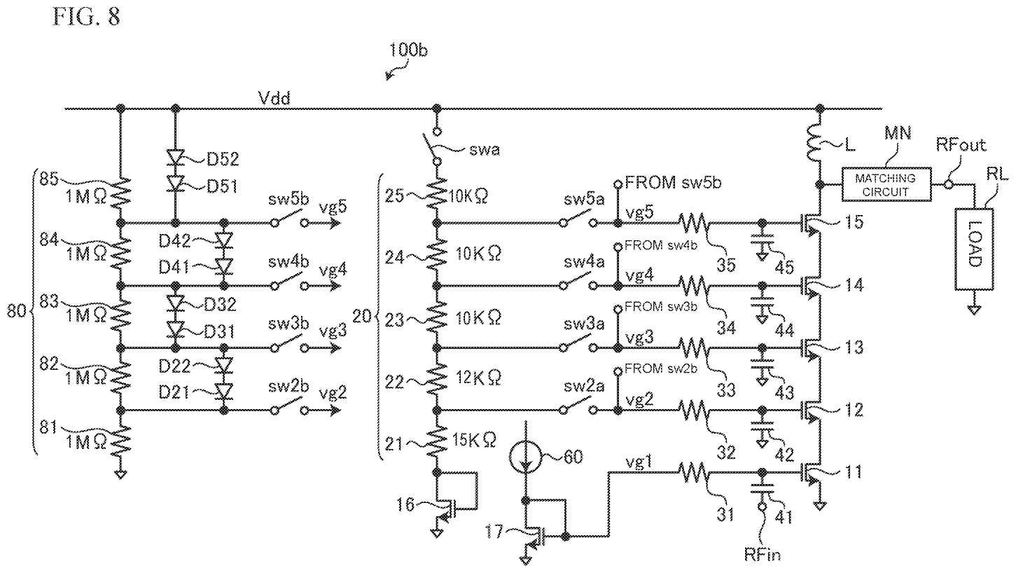

FIG. 8 is a circuit diagram illustrating an amplifier circuit 100b according to the second embodiment. The amplifier circuit 100b corresponds to the amplifier circuit 101 or 102 at the driver stage in FIG. 1. In FIG. 8, the amplifier circuit 100b is a configuration in which diodes are added to the amplifier circuit 100a described with reference to FIG. 3. As illustrated in FIG. 8, diodes are connected in parallel to each resistor in the second voltage divider resistor circuit 80. That is, diodes D21 and D22 are connected in parallel to the resistor 82. Diodes D31 and D32 are connected in parallel to the resistor 83. Diodes D41 and D42 are connected in parallel to the resistor 84. Diodes D51 and D52 are connected in parallel to the resistor 85. The anode of each of these diodes is connected to the power supply Vdd side. The cathode of each of these diodes is connected to the reference potential side. These diodes are first diodes connected in parallel to the resistors included in the voltage divider resistor circuit 80.

Here, in FIG. 8, the number of the first diodes connected in parallel to each resistor is two. In other words, diodes connected in series in two stages are connected in parallel to each resistor. Regarding the first diodes, the number of stages, i.e., the number of diodes connected in series, is adjusted so that the total threshold voltage (i.e., forward voltage VF) is less than or equal to the breakdown voltage of each FET. In other words, one first diode may be connected, or three or more first diodes may be connected.

Here, if the voltage value of the power supply Vdd is 5.5 [V], the potential difference due to the resistance of each stage of the voltage divider resistor circuit 80 is about 1.1 [V]. The threshold of the diodes connected in series in two stages is about 1.4 [V]. Therefore, the diodes connected in two stages do not turn on under normal circumstances. In contrast, the potential difference increases during transient response, and when the potential difference exceeds the threshold, the diodes connected in two stages turn on. Therefore, the potential difference can be limited by the diodes connected in two stages.

That is, for example, when the voltage of the power supply Vdd is at its maximum value within the operating range, if a voltage exceeding the voltage division ratio of the voltage divider resistor circuit 80 is applied, the diodes turn on. With the diodes turning on, this causes a rapid transition to a potential difference similar to the normal operating state. Additionally, instead of the diodes mentioned above, diode-connected FETs may be employed.

By the way, among the resistors 81 to 85 of the voltage divider resistor circuit 80, for the resistor 81 closest to the reference potential, no large potential is applied across both ends thereof. That is, no large potential is applied to the resistor 81 for generating the bias vg2. Thus, no diodes are connected in parallel to the resistor 81. This can limit the current flowing through all the diodes even when each diode turns on. Especially in the case where the circuit becomes hot, the threshold voltage may decrease, causing the diodes to remain in the on state. Even in such a case, the current flowing through the diodes can be suppressed. Therefore, the flow of large leakage current can be suppressed.

### Operation

As illustrated in FIG. 8, as countermeasures against voltage fluctuations of the power supply Vdd in a standby mode, the voltage divider resistor circuit 80 is provided, including resistors with resistance values greater than those of the resistors in the voltage divider resistor circuit 20, and diodes are further connected in parallel to each resistor. Therefore, with the diodes turning on, this causes a rapid transition to a potential difference similar to the normal operating state.

### Effects

In a standby mode where amplification operation is not performed, it is possible to control the bias applied to the gate of each FET, following the voltage fluctuations of the power supply Vdd, while suppressing leakage current as well, thereby realizing the operation not exceeding the breakdown voltage. By suppressing the leakage current, optional power consumption can be prevented. Especially in a communication device powered by a battery, reducing power consumption can extend the battery life. In addition, since the leakage current can be suppressed simply by adding diodes, it is optional to perform complicated control for suppressing the leakage current.

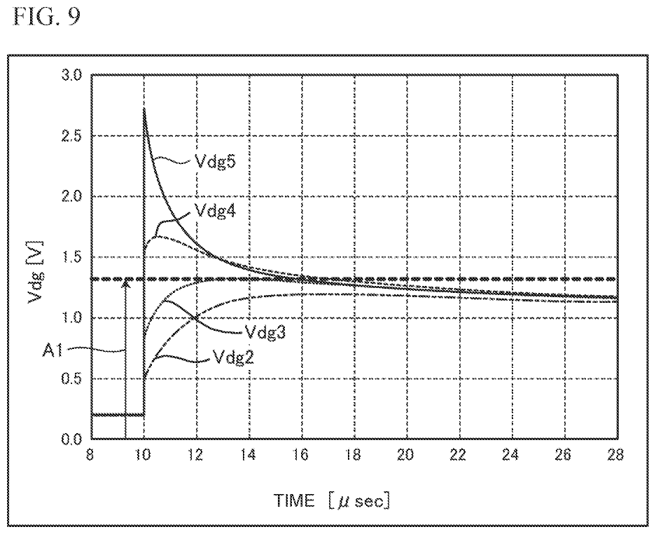

Here, FIG. 9 is a diagram illustrating simulation results for the case where the diodes in FIG. 8 are not connected. In FIG. 9, the horizontal axis indicates the time [μs], and the vertical axis indicates the value [V] of the drain-gate voltage Vdg. In FIG. 9, the voltage Vdg2 is the drain-gate voltage of an FET 12, the voltage Vdg3 is the drain-gate voltage of an FET 13, the voltage Vdg4 is the drain-gate voltage of an FET 14, and the voltage Vdg5 is the drain-gate voltage of an FET 15. In FIG. 9, as the voltage value of the power supply Vdd changes instantaneously from 1.0 [V] to 5.5 [V], the peak value of the drain-gate voltage is about 2.5 [V], and the time exceeding the unbroken area A1 is about 6 [μs].

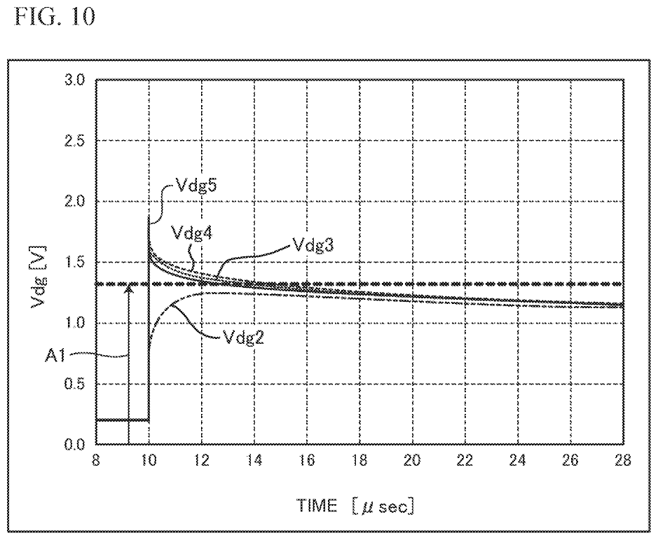

In the meantime, FIG. 10 is a diagram illustrating the operation in the case where diodes are connected as in FIG. 8. In FIG. 10, the horizontal axis indicates the time [μs], and the vertical axis indicates the value [V] of the drain-gate voltage Vdg. In FIG. 10, as the voltage value of the power supply Vdd changes from 1.0 [V] to 5.5 [V] during 10 [nsec], the peak value of the drain-gate voltage is about 1.9 [V], and the time exceeding the unbroken area A1 is about 4 [μs]. In this way, the peak value of the drain-gate voltage can be suppressed, and the time exceeding the unbroken area A1 can be shortened.

### Third Embodiment

A third embodiment will now be described.

### Configuration

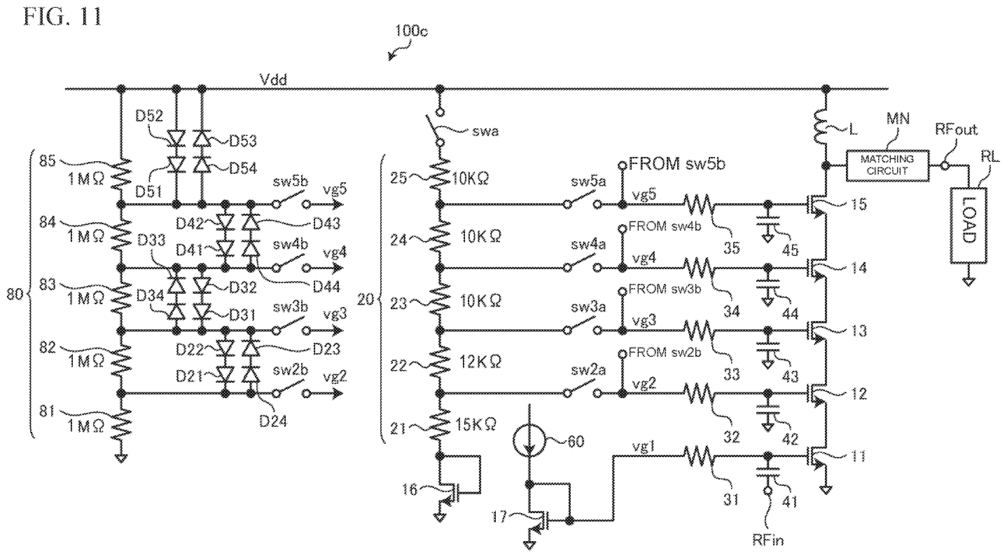

FIG. 11 is a circuit diagram illustrating an amplifier circuit 100c according to the third embodiment. The amplifier circuit 100c corresponds to the amplifier circuit 101 or 102 at the driver stage in FIG. 1. In FIG. 11, the amplifier circuit 100c is a configuration in which diodes are further added to the amplifier circuit 100b described with reference to FIG. 8, with the diodes connected bidirectionally. As illustrated in FIG. 11, diodes are further connected in parallel to each of the resistors in the second voltage divider resistor circuit 80. That is, diodes D23 and D24 are connected in parallel to the resistor 82. Diodes D33 and D34 are connected in parallel to the resistor 83. Diodes D43 and D44 are connected in parallel to the resistor 84. Diodes D53 and D54 are connected in parallel to the resistor 85. The anode of each of these diodes is connected to the reference potential side. The cathode of each of these diodes is connected to the power supply Vdd side. These diodes are second diodes connected in parallel to the resistors included in the voltage divider resistor circuit 80.

### Operation

By further connecting the second diodes in parallel to each resistor in the second voltage divider resistor circuit 80, in the case where the voltage value of the power supply Vdd fluctuates, if a voltage exceeding the threshold of the diodes is applied, the diodes turn on, and this causes a rapid transition to a potential difference similar to the normal operating state. Therefore, during the transition from a high voltage value to a low voltage value, i.e., during the drop, it is possible to suppress delays caused by the time constant.

### Effects

As in the case of the second embodiment, by suppressing the leakage current, optional power consumption can be suppressed. Especially in a communication device powered by a battery, reducing power consumption can extend the battery life. Also, by further connecting the second diodes in parallel to each resistor in the second voltage divider resistor circuit 80, when the power supply Vdd transitions from a high voltage value to a low voltage value, i.e., during the drop, it is possible to suppress delays caused by the time constant.

### Modification

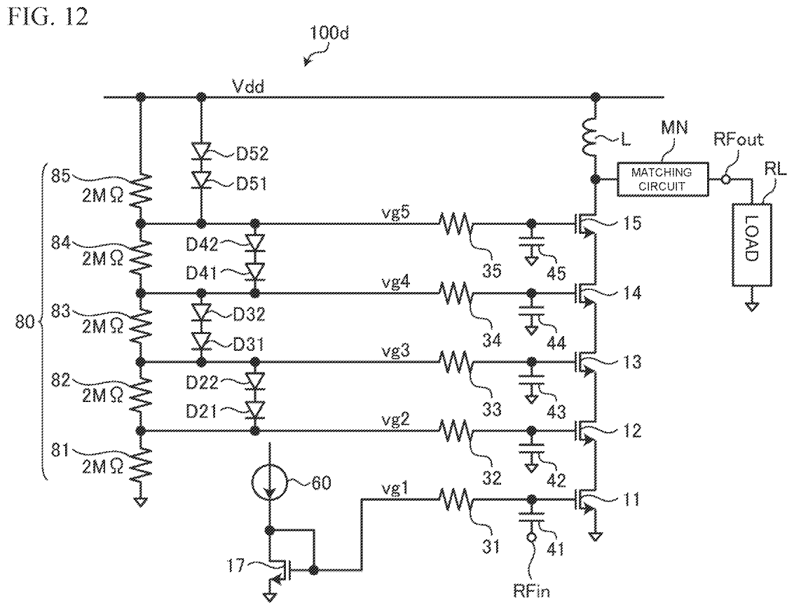

FIG. 12 is a circuit diagram illustrating an amplifier circuit 100d according to a modification. The amplifier circuit 100d illustrated in FIG. 12 has a configuration in which the first voltage divider resistor circuit 20, the FET 16, the switch swa, and the other switches are removed from the amplifier circuit 100b described with reference to FIG. 8. The amplifier circuit 100d is illustrated focusing on the second voltage divider resistor circuit 80 in FIG. 8. In FIG. 12, the voltage divider resistor circuit 80 is provided between the power supply Vdd and the reference potential. The voltage divider resistor circuit 80 includes the resistors 81, 82, 83, 84, and 85. The voltage divider resistor circuit 80 divides the potential difference between the power supply Vdd and the reference potential, and generates biases to be applied to the gates of the FET 12 to the FET 15. The resistance value of each resistor in the voltage divider resistor circuit 80 is greater than the resistance value of each resistor included in the first voltage divider resistor circuit 20 of the amplifier circuit 100b described with reference to FIG. 8.

As illustrated in FIG. 12, diodes are connected in parallel to each resistor in the second voltage divider resistor circuit 80. That is, diodes D21 and D22 are connected in parallel to the resistor 82. Diodes D31 and D32 are connected in parallel to the resistor 83. Diodes D41 and D42 are connected in parallel to the resistor 84. Diodes D51 and D52 are connected in parallel to the resistor 85. The anode of each of these diodes is connected to the power supply Vdd side. The cathode of each of these diodes is connected to the reference potential side. These diodes are first diodes connected in parallel to the resistors included in the voltage divider resistor circuit 80.

Here, if the voltage value of the power supply Vdd is 5.5 [V], the potential difference due to the resistance of each stage of the voltage divider resistor circuit 80 is about 1.1 [V]. The threshold of the diodes connected in series in two stages is about 1.4 [V]. Therefore, the diodes connected in two stages do not turn on under normal circumstances. In contrast, the potential difference increases during transient response, and when the potential difference exceeds the threshold, the diodes connected in two stages turn on. Therefore, the potential difference can be limited by the diodes connected in two stages. That is, for example, when the voltage of the power supply Vdd is at its maximum value within the operating range, if a voltage exceeding the voltage division ratio of the voltage divider resistor circuit 80 is applied, the diodes turn on. With the diodes turning on, this causes a rapid transition to a potential difference similar to the normal operating state. Additionally, instead of the diodes mentioned above, diode-connected FETs may be employed.

Like the amplifier circuit 100b described with reference to FIG. 8, among the resistors 81 to 85 of the voltage divider resistor circuit 80, for the resistor 81 closest to the reference potential, no large potential is applied across both ends thereof. That is, no large potential is applied to the resistor 81 for generating the bias vg2. Thus, no diodes are connected in parallel to the resistor 81. This can limit the current flowing through all the diodes even when each diode turns on. Especially in the case where the circuit becomes hot, the threshold voltage may decrease, causing the diodes to remain in the on state. Even in such a case, the current flowing through the diodes can be suppressed. Therefore, the flow of large leakage current can be suppressed.

As described above, the amplifier circuit 100d includes the input terminal RFin to which a signal to be amplified is input, the first FET 11 having a gate to which the signal input to the input terminal RFin is applied, the second FET 12 connected, together with the first FET 11, between the power supply Vdd and the reference potential, and the output terminal RFout provided between the second FET 12 and the load RL to output the amplified signal. The first FET 11 and the second FET 12 have their adjacent drains and sources connected.

In addition, the amplifier circuit 100d includes the voltage divider resistor circuit 80 which divides the potential difference between the power supply Vdd and the reference potential, and generates a bias to be applied to the gate of the second FET 12, and the first diodes D21, D22, D31, D32, D41, D42, D51, and D52 connected in parallel to the resistors 82 to 85 included in the voltage divider resistor circuit 80. The anode of each first diode is connected to the power supply Vdd side of each resistor of the voltage divider resistor circuit 80, and the cathode of each first diode is connected to the reference potential side of each resistor of the voltage divider resistor circuit 80. Note that, of the resistors included in the voltage divider resistor circuit 80, no first diode is connected to the resistor 81 closest to the reference potential side.

### Operation

As illustrated in FIG. 8, as countermeasures against voltage fluctuations of the power supply Vdd in a standby mode, the voltage divider resistor circuit 80 is provided, including resistors with resistance values greater than those of the resistors in the voltage divider resistor circuit 20, and diodes are further connected in parallel to each resistor. Therefore, with the diodes turning on, this causes a rapid transition to a potential difference similar to the normal operating state.

### Effects

In a standby mode where amplification is not performed, it is possible to control the bias applied to the gate of each FET, following the voltage fluctuations of the power supply Vdd, while suppressing leakage current as well, thereby realizing the operation not exceeding the breakdown voltage. By suppressing the leakage current, optional power consumption can be prevented. Especially in a communication device powered by a battery, reducing power consumption can extend the battery life. In addition, since the leakage current can be suppressed simply by adding diodes, it is optional to perform complicated control for suppressing the leakage current.

### Power Amplifier Circuit and Communication Device

As described with reference to FIG. 1, any of the above-described amplifier circuits 100a to 100c may be used as a driver-stage amplifier circuit, and a power-stage amplifier circuit may be further provided, with the output of the driver-stage amplifier circuit serving as input, thereby forming a power amplifier circuit. In doing so, a power amplifier circuit suitable for use in a communication device or the like can be realized.

As described with reference to FIG. 1, a plurality of power amplifier circuits each including a driver-stage amplifier circuit and a power-stage amplifier circuit may be provided in or on a communication device, and these power amplifier circuits may be selectively operated. In the communication device 1000 illustrated in FIG. 1, two power amplifier circuits M1 and H1 are provided in or on the communication device. As described above, the power amplifier circuits M1 and H1 are formed as separate PA modules. Then, the power amplifier circuits M1 and H1 selectively perform amplification operation according to the voltage supplied by the common power supply Vdd. With such a configuration, a communication device that can suppress power consumption due to leakage current can be realized.

With respect to the description of the claims, the present disclosure can take the following aspects.
<1> An amplifier circuit including:
an input terminal to which a signal to be amplified is input;
a first FET having a gate to which the signal input to the input terminal is applied;
a second FET connected, together with the first FET, between a power supply and a reference potential;
an output terminal provided between the second FET and a load to output an amplified signal;
a first voltage divider resistor circuit that divides a potential difference between the power supply and the reference potential, and generates a bias to be applied to a gate of the second FET; and
a first switch element provided between the first voltage divider resistor circuit and the power supply and for turning on/off an electrical connection between the power supply and the first voltage divider resistor circuit,
wherein the first FET and the second FET have their adjacent drains and sources connected, and
the first switch element turns off when amplification operation by the first FET and the second FET is not performed.
<2> The amplifier circuit according to <1>, further including:
a second voltage divider resistor circuit that divides a potential difference between the power supply and the reference potential, and generates a bias to be applied to the gate of the second FET,
wherein a resistance value of each of resistors included in the second voltage divider resistor circuit is greater than a resistance value of each of resistors included in the first voltage divider resistor circuit.
<3> The amplifier circuit according to <2>, further including:
a first diode connected in parallel to a resistor included in the second voltage divider resistor circuit,
wherein an anode of the first diode is connected to the power supply side of the resistor, and
a cathode of the first diode is connected to the reference potential side of the resistor.
<4> The amplifier circuit according to <3>, further including:
a second diode connected in parallel to a resistor included in the second voltage divider resistor circuit,
wherein an anode of the second diode is connected to the reference potential side of the resistor, and
a cathode of the second diode is connected to the power supply side of the resistor.
<5> The amplifier circuit according to <3>, wherein:
the first diode is not connected to a resistor closest to the reference potential side, among the resistors included in the second voltage divider resistor circuit.
<6> The amplifier circuit according to any one of <2> to <5>, further including:
a second switch element provided between the first voltage divider resistor circuit and the second FET; and
a third switch element provided between the second voltage divider resistor circuit and the second FET,
wherein a bias is supplied from the first voltage divider resistor circuit to the second FET by way of the second switch element, and
a bias is supplied from the second voltage divider resistor circuit to the second FET by way of the third switch element.
<7> The amplifier circuit according to <6>, wherein:
the first switch element
   turns on when the second switch element turns on, and
   turns off when the second switch element turns off, and
the second switch element
   turns off when the third switch element turns on, and
   turns on when the third switch element turns off.
<8> The amplifier circuit according to any one of <1> to <7>, wherein a voltage value of the power supply fluctuates.
<9> A power amplifier circuit in which the amplifier circuit according to any one of <1> to <8> serves as a driver-stage amplifier circuit, the power amplifier circuit further including a power-stage amplifier circuit, with output of the driver-stage amplifier circuit serving as input.
<10> The power amplifier circuit according to <9>, wherein the power-stage amplifier circuit is configured by a bipolar transistor.
<11> A communication device including a plurality of the power amplifier circuits according to <9> or <10>, wherein the plurality of the power amplifier circuits selectively perform amplification operation according to a voltage supplied by a common power supply.
<12> An amplifier circuit including:
an input terminal to which a signal to be amplified is input;
a first FET having a gate to which the signal input to the input terminal is applied;
a second FET connected, together with the first FET, between a power supply and a reference potential;
an output terminal provided between the second FET and a load to output an amplified signal;
a voltage divider resistor circuit that divides a potential difference between the power supply and the reference potential, and generates a bias to be applied to a gate of the second FET; and
a first diode connected in parallel to a resistor included in the voltage divider resistor circuit,
wherein an anode of the first diode is connected to the power supply side of the resistor,
a cathode of the first diode is connected to the reference potential side of the resistor, and
the first FET and the second FET have their adjacent drains and sources connected.
<13> The amplifier circuit according to <12>, wherein:
the first diode is not connected to a resistor closest to the reference potential side, among resistors included in the voltage divider resistor circuit.

What is claimed is:

1. An amplifier circuit comprising:
an input terminal to which a signal is input;
a first field effect transistor (FET) having a gate to which the signal input to the input terminal is applied;
a second FET connected, together with the first FET, between a power supply and a reference potential;
an output terminal between the second FET and a load, and that is configured to output an amplified signal;
a first voltage divider resistor circuit configured to divide a potential difference between the power supply and the reference potential, and to generate a first bias applied to a gate of the second FET; and
a first switch between the first voltage divider resistor circuit and the power supply, and that is configured to switch an electrical connection between the power supply and the first voltage divider resistor circuit,
wherein a source of the first FET is connected to a drain of the second FET, and
wherein the first switch is configured to disconnect the electrical connection when an amplification operation by the first FET and the second FET is not performed.

2. The amplifier circuit according to claim 1, further comprising:
a second voltage divider resistor circuit configured to divide the potential difference between the power supply and the reference potential, and to generate a second bias applied to the gate of the second FET,
wherein a resistance value of each of a plurality of resistors in the second voltage divider resistor circuit is greater than a resistance value of each of a plurality of resistors in the first voltage divider resistor circuit.

3. The amplifier circuit according to claim 2, further comprising:
a first diode connected in parallel to a resistor in the second voltage divider resistor circuit,
wherein an anode of the first diode is connected to a power supply side of the resistor, and
wherein a cathode of the first diode is connected to a reference potential side of the resistor.

4. The amplifier circuit according to claim 3, further comprising:
a second diode connected in parallel to a resistor in the second voltage divider resistor circuit,
wherein an anode of the second diode is connected to a reference potential side of the resistor, and
wherein a cathode of the second diode is connected to a power supply side of the resistor.

5. The amplifier circuit according to claim 3, wherein the first diode is not connected to the resistor in the second voltage divider resistor circuit that is closest to the reference potential.

6. The amplifier circuit according to claim 2, further comprising:
a second switch between the first voltage divider resistor circuit and the second FET; and
a third switch between the second voltage divider resistor circuit and the second FET,
wherein the bias generated by the first voltage divider resistor circuit is supplied to the second FET by way of the second switch, and
wherein the bias generated by the second voltage divider resistor circuit is supplied to the second FET by way of the third switch.

7. The amplifier circuit according to claim 6,
wherein the first switch is configured to connect the electrical connection when the second switch connects the first voltage divider resistor circuit to the second FET, and to disconnect the electrical connection when the second switch disconnects the first voltage divider resistor circuit from the second FET, and
wherein the second switch is configured to disconnect the first voltage divider resistor circuit from the second FET when the third switch connects the second voltage divider resistor circuit to the second FET, and to connect the first voltage divider resistor circuit to the second FET when the third switch disconnects the second voltage divider resistor circuit from the second FET.

8. The amplifier circuit according to claim 1, wherein a voltage value of the power supply fluctuates.

9. A power amplifier comprising:
a driver-stage amplifier circuit comprising the amplifier circuit according to claim 1; and
a power-stage amplifier circuit,
wherein the amplified signal output from the output terminal of the driver-stage amplifier circuit is input to the power-stage amplifier circuit.

10. The power amplifier circuit according to claim 9, wherein the power-stage amplifier circuit comprises a bipolar transistor.

11. A communication device comprising a plurality of the power amplifiers according to claim 9, wherein the plurality of the power amplifiers are configured to selectively perform an amplification operation according to a voltage supplied by a common power supply.
